(19) United States
(12) Patent Application Publication
(10) Pub. No.: US 2006/0221721 A1
(43) Pub. Date: Oct. 5, 2006

(54) Computer system, storage device and computer software and data migration method

(75) Inventors: Toru Tanaka, Kawasaki (JP); Yasunori Kaneda, Sagamihara (JP); Yuichi Taguchi, Sagamihara (JP); Masayuki Yamamoto, Sagamihara (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hitachi, Ltd., Tokyo (JP)

(21) Appl. No.: 11/133,771

(22) Filed: May 19, 2005

(30) Foreign Application Priority Data
Mar. 17, 2005 (JP) 2005-077605

(51) Int. Cl. G11C 7/10

(52) U.S. Cl. 365/189.05

(57) ABSTRACT

To provide a data copy capability of copying data between storage devices while maintaining the data integrity even if the copy process is interrupted in a hierarchical connection arrangement of storage devices.

A computer system includes a computer 100 and a plurality of storage devices 140, 160 connected to the computer 100 via a network, in which one storage device 140 has a first storage area 151, allows the computer 100 to access a second storage area 170 in one or more other storage devices 160 via the storage device 140, allocates the first storage area for copy of data from the second storage area 170 and copies data from the second storage area 170 into a first storage area 150.

The present application is based on and claims priority of Japanese patent applications No. 2005-077605 filed on Mar. 17, 2005, the entire contents of which are hereby incorporated by reference.

### BACKGROUND OF THE INVENTION

1. Field of the Invention

The present invention relates to a data migration method for a storage system. In particular, it relates to a technique of improving the data integrity in a data migration process between hierarchical storage devices.

2. Description of the Related Art

In recent years, with the improvement of the performance of computers and with the increase of the Internet line speed, the amount of data processed by computers increases. In order to maintain an increasing amount of data for a long time over the lifetime of a storage device, when the storage device reaches the end of the lifetime, the data in the storage device has to be migrated into a new storage device. It is preferred that a computer can access (read or write) data without interruption during the data copying from the old storage device into the new storage device. National Publication of International Patent Application No. 1998-508967 (Patent Document 2) discloses a technique of copying data without interruption of access by a computer. Besides, Japanese Patent Laid-Open No. 2004-5370 (Patent Document 1) discloses a technique of using an old storage device via a new storage device without data copying.
[Patent Document 1] Japanese Patent Laid-Open No. 2004-5370
[Patent Document 2] National Publication of International Patent Application No. 1998-508967

### SUMMARY OF THE INVENTION

In National Publication of International Patent Application No. 1998-508967 (Patent Document 2), there is disclosed a technique of copying data in an old storage device into a new storage device while processing an access from a computer. According to this disclosed technique, the computer uses a storage area (volume) of the migration-destination storage device and refers to a volume of the migration-source storage device for data that has not been copied into the volume of the migration-destination storage device. However, according to this technique, the computer cannot use the volume of the migration-source storage device if the copy process is interrupted (including a case where it is interrupted due to a failure or the like).

In Japanese Patent Laid-Open No. 2004-5370 (Patent Document 1), there is disclosed a technique for a computer to use an old storage device via a new storage device. Since the computer can use data in the old storage device without copying the data into the new storage device, if the arrangement of the storage system is modified, data copy is not essential, and the computer can resume accessing the storage system immediately after the modification. Therefore, the data can be copied from the old storage device into the new storage device at any convenient time after the modification.

Thus, an object of the present invention is to provide a capability of copying data between storage devices while maintaining the data integrity even if the copy process is interrupted in the hierarchical connection arrangement of storage devices (referred to as an external connection arrangement hereinafter) disclosed in Japanese Patent Laid-Open No. 2004-5370 (Patent Document 1).

In order to attain the object, the present invention provides a computer system comprising: a computer; a first storage device connected to the computer; a second storage device connected to the first storage device; and a network interconnecting the computer, the first storage device and the second storage device, in which the computer system has access means that allows the computer to access a second volume in the second storage device via the first storage device, allocation means for allocating a first volume of the first storage device for copy of data from the second volume into the first storage device, and copy means for copying data from the second volume into the first volume, and the data written by the computer during data copying by the copy means from the second volume into the first volume is saved only in the first volume.

That is, the present invention provides a computer system comprising: a computer; and a plurality of storage devices connected to the computer via a network, in which one of the storage devices has a first storage area, allows the computer to access a second storage area in one or more other storage devices via itself, allocates the first storage area for copy of data from the second storage area and copies data from the second storage area into the first storage area.

According to the present invention, in the external connection arrangement, an old storage device can be used under a new storage device, a computer can use data in the old storage device via the new storage device, and the timing to copy data from the old storage device into the new storage device can be controlled. In addition, the complete data before the start of copying can be retained in the old storage device, and therefore, even if data copying is interrupted or has to be interrupted after data copying is started at any convenient time, the computer can resume processing immediately after the interruption using the data retained in the volume of the old storage device.

In addition, if consecutive data copying of a plurality of volumes is interrupted or has to be interrupted, the computer can select the complete data before the start of copying with respect to the volumes having been completely copied, and the computer can use the complete data before the start of copying even if a plurality of volumes are incompletely copied.

In addition, extraction means for extracting separately the data written by the computer during copying and extracted data writing means allow the data written until the copying is interrupted to be reflected to the volume in the old storage device storing the complete data before the start of data copying. This reflection can be selected depending on the processing procedure, and the status before the start of copying or the status immediately before the copy is interrupted can be recovered.

### BRIEF DESCRIPTION OF THE DRAWINGS

FIG. 1 shows a system arrangement according to an embodiment 1;

FIG. 2 shows an arrangement of a memory of a host according to the embodiment 1;

FIG. 3 shows an arrangement of a memory of a manager host according to the embodiment 1;

FIG. 4 shows an arrangement of a memory of an FC switch according to the embodiment 1;

FIG. 5 shows an arrangement of a memory of an IP switch according to the embodiment 1;

FIG. 6 shows an arrangement of a memory of a migration-destination storage device according to the embodiment 1;

FIG. 7 shows an arrangement of a memory of a migration-source storage device according to the embodiment 1;

FIG. 8 shows an example 1 of a recovery condition configuration TBL according to the embodiment 1;

FIG. 9 shows an example 1 of a host configuration TBL according to the embodiment 1;

FIG. 10 shows an FC switch configuration TBL according to the embodiment 1;

FIG. 11 shows an IP switch configuration TBL according to the embodiment 1;

FIG. 12 shows an example 1 of a migration-destination storage device configuration TBL according to the embodiment 1;

FIG. 13 shows an example 1 of an allocation configuration TBL according to the embodiment 1;

FIG. 14 shows an example 1 of a copy status managing TBL according to the embodiment 1;

FIG. 15 shows an example 1 of a migration-destination storage device configuration TBL according to the embodiment

FIG. 16 shows a flow of a host I/O processing in an external connection arrangement according to the embodiment 1;

FIG. 17 is a diagram illustrating a configuration acquisition processing before data copying according to the embodiment 1;

FIG. 18 is a diagram illustrating a data copy procedure according to the embodiment 1;

FIG. 19 shows an example 2 of the allocation configuration TBL according to the embodiment 1;

FIG. 20 shows an example 2 of the host configuration TBL according to the embodiment 1;

FIG. 21 is a diagram illustrating an I/O request processing during data copying according to the embodiment 1;

FIG. 22 is a diagram illustrating a recovery processing for recovering data copy interruption according to the embodiment 1;

FIG. 23 shows a recovery procedure creation processing according to the embodiment 1;

FIG. 24 shows a post-recovery processing according to the embodiment 1;

FIG. 25 shows a recovery condition selection screen according to the embodiment 1;

FIG. 26 shows a system arrangement according to an embodiment 2;

FIG. 27 shows an example 1 of a recovery condition configuration TBL according to the embodiment 2;

FIG. 28 shows an example 1 of a copy status managing TBL according to the embodiment 2;

FIG. 29 shows an example 1 of an allocation configuration TBL according to the embodiment 2;

FIG. 30 shows an example 1 of a migration-destination storage device configuration TBL according to the embodiment 2;

FIG. 31 shows an example 2 of the migration-destination storage device configuration TBL according to the embodiment 2;

FIG. 32 shows an example 1 of a host configuration TBL according to the embodiment 2;

FIG. 33 shows an example 2 of the host configuration TBL according to the embodiment 2;

FIG. 34 shows an example 3 of the migration-destination storage device configuration TBL according to the embodiment 2;

FIG. 35 shows an example 4 of the migration-destination storage device configuration TBL according to the embodiment 2; and

FIG. 36 shows an example 3 of the host configuration TBL according to the embodiment 2.

### DETAILED DESCRIPTION OF THE PREFERRED EMBODIMENTS

In the following, best modes for carrying out the present invention will be described in detail.

Embodiments of a computer system, a storage device and computer software and a data migration method according to the present invention will be described with reference to the drawings.

### Embodiment 1

An embodiment 1 will be described schematically. According to this embodiment, a migration-source storage device 160 and a migration-destination storage device 140 are connected to an FC switch 120, and volumes 151 and 152 in the migration-destination storage device 140 are assumed as virtual volumes 171 and 172 in the migration-source storage device 160, respectively, and data in the volume 151 is copied into the volume 150.

FIG. 1 shows a system arrangement according to this embodiment. In FIG. 1, a host 100 is a computer that accesses the migration-source storage device 160 before migration and comprises an FC I/F 101 for transmitting/receiving input/output data to/from the migration-source storage device 160, an IP I/F 105 for transmitting/receiving management data to/from a manager host 110, a CPU 102 for executing a program and controlling the whole of the host, a memory 107 for providing a storage area for a program, a storage unit 106 for storing a program, user data or the like, an input unit 103 that permits a user to input information, such as a keyboard and a mouse, and an output unit 104 for displaying information to a user, such as a display.

The manager host 110 is a computer that manages the host 100, the migration-source storage device 160 and the migration-destination storage device 140 and comprises an FC I/F 111 for transmitting input data and control data to or receiving output data from the migration-source storage device 160 and the migration-destination storage device 140, an IP I/F 115 for transmitting or receiving management data to or from the host 100, the migration-source storage device 160 and the migration-destination storage device 140, a CPU 112 for executing a program and controlling the whole of the manager host, a memory 117 for providing a storage area for a program, a storage unit 116 for storing a program, user data or the like, an input unit 113 that permits a user to input information, such as a keyboard and a mouse, and an output unit 114 for displaying information to a user, such as a display.

The FC switch 120 serves to transfer input/output data from the host 100 to the migration-source storage device 160 and comprises FC I/Fs 121, 122, 127, 128 and 129 for transmitting/receiving input/output data, an IP I/F 123 for transmitting/receiving management data, a CPU 124 for executing a program and controlling the whole of the FC switch, and a memory 125 for providing a storage area for a program.

An IP switch 130 serves to transfer management data from the manager host 110 to the host 100 or the like and comprises IP I/Fs 131, 132, 133, 135, 136 and 137 for transmitting/receiving input/output data, a CPU 134 for executing a program and controlling the whole of the IP switch, and a memory 135 for providing a storage area for a program.

The migration-destination storage device 140 is a node for processing input/output data from the host 100 and comprises FC IFs 141 and 142 for receiving input/output data transferred from the FC switch, an IP I/F 143 for receiving management data from the manager host, a CPU 144 for executing a program and controlling the whole of the migration-destination storage device, a memory 145 for providing a storage area for a program, disk units 147 and 148 for storing user data, a storage controller 146 for controlling the disk units, volumes 149 and 150, which are sections of the disk units that are visible to the user, and volumes 151 and 152, which are virtual internal volumes of the migration-destination storage device 140 that mimic the volumes of the migration-source storage device 160 in order for use in the external connection arrangement.

The migration-source storage device 160 is a node for processing input/output data from the host 100 and comprises FC IFs 162 and 163 for receiving input/output data transferred from the FC switch, an IP I/F 161 for receiving management data from the manager host, a CPU 164 for executing a program and controlling the whole of the migration-source storage device, a memory 165 for providing a storage area for a program, disk units 167 and 168 for storing user data, a storage controller 166 for controlling the disk units, and volumes 169, 170, 171 and 172, which are sections of the disk units that are visible to the user.

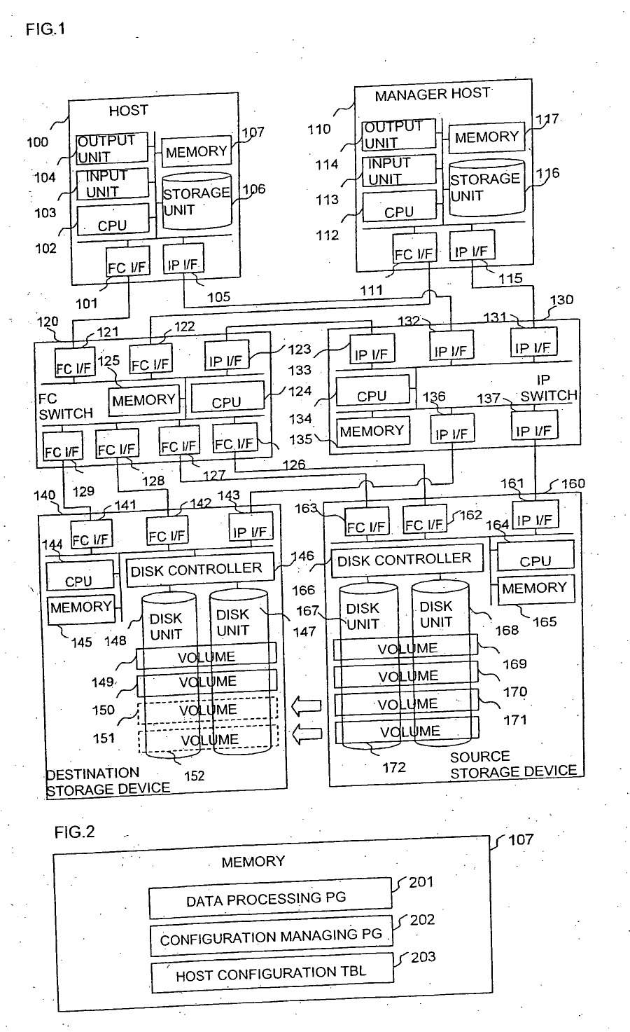

FIG. 2 shows an arrangement of the memory 107 of the host. Upon boot-up, the host 100 reads, into the memory 107, a data processing program (abbreviated as PG, hereinafter) 201 for transmitting/receiving data to/from the migration-source storage device 160, a configuration managing PG 202 for managing the configuration information about the host, and a host configuration table (abbreviated as TBL hereinafter) 203 containing the configuration information about the host.

FIG. 3 shows an arrangement of the memory 117 of the manager host. Upon boot-up, the manager host 110 reads, into the memory 117, an allocation controlling command PG 301 for issuing an allocation controlling command indicating pair generation or pair canceling between the migration-source storage device 160 and the migration-destination storage device 140, a configuration managing PG 302 for managing the configuration information about the manager host, a failure receiving PG 303 for receiving failure information from the destination storage 140 or the like, a recovery condition TBL 304 that defines a recovery condition, a host configuration TBL 203 containing the configuration information about the manager host, an FC switch configuration TBL 306 containing the configuration information about the FC switch, an IP switch configuration TBL 307 containing the configuration information about the IP switch, a migration-destination storage device configuration TBL 308 containing the configuration information about the migration-destination storage device, and a migration-source storage device configuration TBL 309 containing the configuration information about the migration-source storage device.

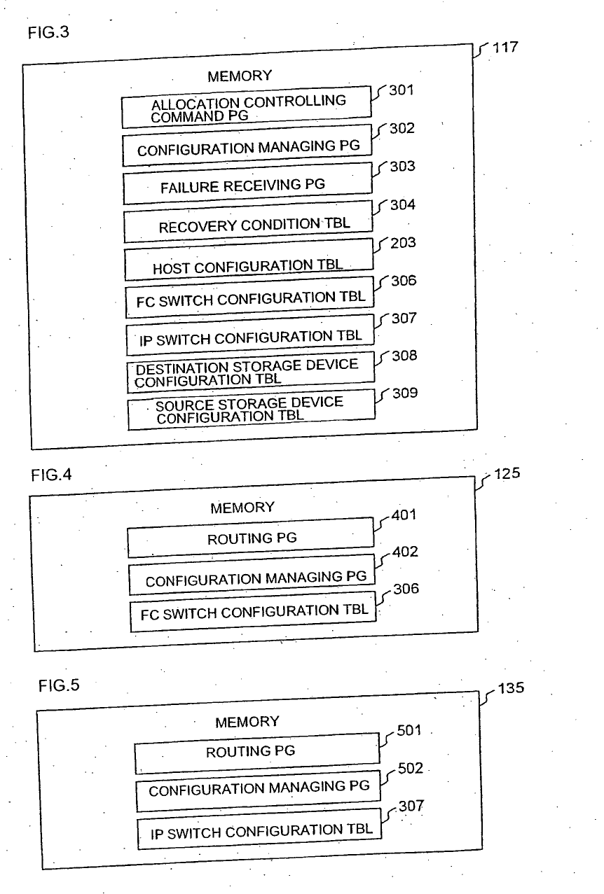

FIG. 4 shows an arrangement of the memory 125 of the FC switch. Upon boot-up, the FC switch 120 reads, into the memory 125, a routing PG 401 for transferring input/output data between the host 100 and the migration-source storage device 160 or the like, a configuration managing PG 402 for managing the configuration information about the FC switch, and an FC switch configuration TBL 306 containing the configuration information about the FC switch.

FIG. 5 shows an arrangement of the memory 135 of the IP switch. Upon boot-up, the IP switch 130 reads, into the memory 135, a routing PG 501 for transferring management data between the manager host 110 and the host 100 or the like, a configuration managing PG 502 for managing the configuration information about the IP switch, and an IP switch configuration TBL 307 containing the configuration information about the IP switch.

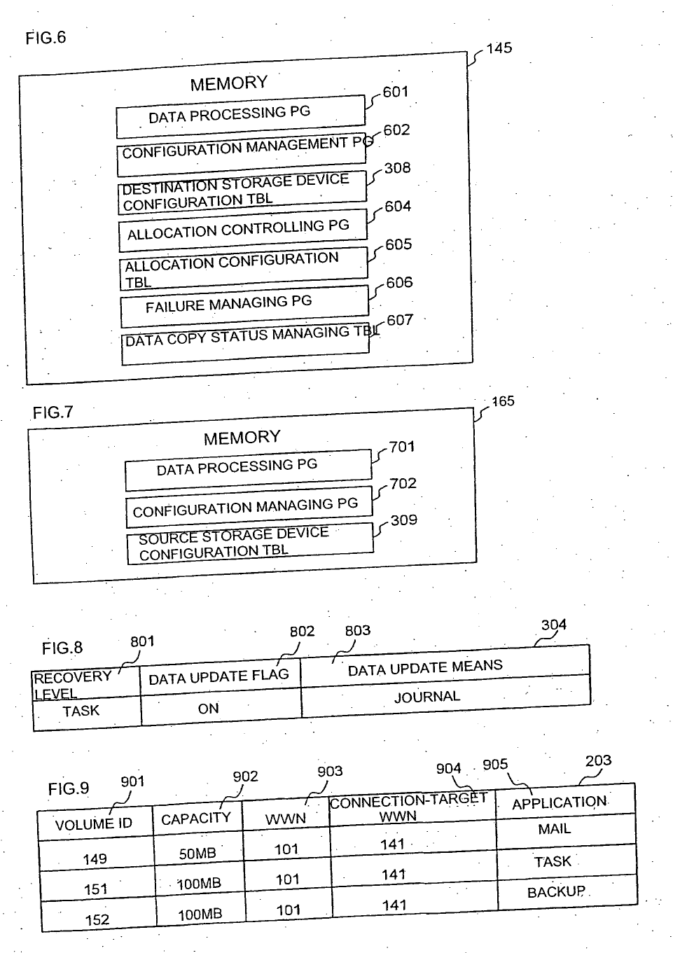

FIG. 6 shows an arrangement of the memory 145 of the migration-destination storage device. Upon boot-up, the migration-destination storage device 140 reads, into the memory 145, a data processing PG 601 for allowing the host 100 to access the migration-source storage device 160 via the migration-destination storage device 140, a configuration management PG 602 for managing the configuration information about the migration-destination storage device, a migration-destination storage device configuration TBL 308 containing the configuration information about the migration-destination storage device, an allocation controlling PG 604 for controlling pair generation or pair canceling between the migration-destination storage device 140 and the migration-source storage device 160 or the like, an allocation configuration TBL 605 containing pair arrangement information, a failure managing PG 606 for detecting a failure in the migration-destination storage device and informing of the failure, and a data copy status managing TBL 607 containing information about the progress of data copying.

FIG. 7 shows an arrangement of the memory 165 of the migration-source storage device 160. Upon boot-up, the migration-source storage device 160 reads, into the memory 165, a data processing PG 701 for transmitting/receiving data to/from the host 100, a configuration managing PG 702 for managing the configuration information about the migration-source storage device, and a migration-source storage device configuration TBL 309 containing the configuration information about the migration-source storage device.

FIG. 8 shows an exemplary arrangement of the recovery condition configuration TBL according to the embodiment 1. The recovery condition configuration TBL 304 contains a recovery level 801 that indicates a recovery range of data in the case where an interruption of data copying occurs, a data update flag 802 that indicates whether to write the data occurring during data copying to the recovery-target volume, and data update means 803 used for updating data in the recovery-target volume (such as differential data about the volume).

FIG. 9 shows an exemplary arrangement of the host configuration TBL. The host configuration TBL 203 contains a volume ID 901 that identifies a volume to which the host is mounted, a capacity 902 of the volume, a WWN 903, which is a port address of the host, a connection-target WWN 904, which is a port address in the connection-target storage device of the volume used by the host, and an application 905 of the volume.

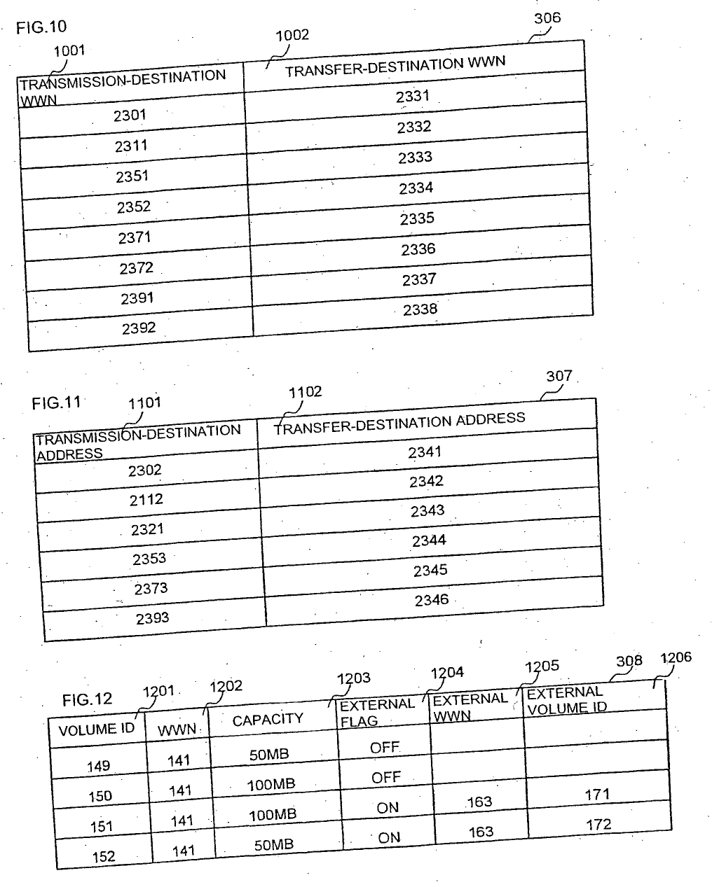

FIG. 10 shows an exemplary arrangement of the FC switch configuration TBL. The FC switch configuration TBL 306 contains a transmission-destination WWN 1001, which is a destination of data, and a transfer-destination WWN 1002, which is a port address for transferring the data to the destination.

FIG. 11 shows an exemplary arrangement of the IP switch configuration TBL. The IP switch configuration TBL 307 contains a transmission-destination address 1101, which is a destination of data, and a transfer-destination address 1102, which is a port address for transferring the data to the destination.

FIG. 12 shows an exemplary arrangement of the migration-destination storage device configuration TBL. The migration-destination storage device configuration TBL 308 contains a volume ID 1201, which is an identifier of a volume defined in the migration-destination storage device, a WWN 1202, which is a port address of the migration-destination storage device, a capacity 1203 of the relevant volume, an external flag 1204 that indicates whether the relevant volume is used in the external connection arrangement, an external WWN 1205, which is a port address of the external storage device in the case where the relevant volume is used in the external connection arrangement, and an external volume ID 1206, which is an identifier of the volume in the external storage device.

FIG. 13 shows an exemplary arrangement of the allocation configuration TBL. The allocation configuration TBL 605 contains a copy-source volume ID 1301, which is an identifier of a copy-source volume of a pair, and a copy-destination volume ID 1302, which is an identifier of a copy-destination volume of the pair.

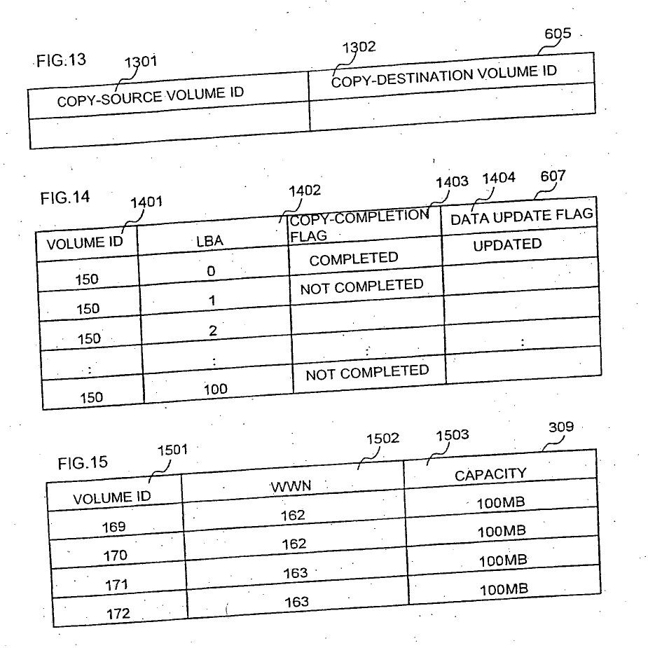

FIG. 14 shows an exemplary arrangement of the copy status managing TBL. The copy status managing TBL 607 contains a volume ID 1401, which is an identifier of a copy-source volume, an LBA 1402, which is a logical address of a block constituting the volume, a copy-completion flag 1403 that indicates whether data copying for the relevant LBA is completed, and a data update flag 1404 that indicates whether the relevant LBA is updated.

FIG. 15 shows an exemplary arrangement of the migration-destination storage device configuration TBL. The migration-destination storage device configuration TBL 309 contains a volume ID 1501, which is an identifier of a volume defined in the migration-destination storage device, a WWN 1502, which is a port address of the migration-destination storage device, and a capacity 1503 of the volume.

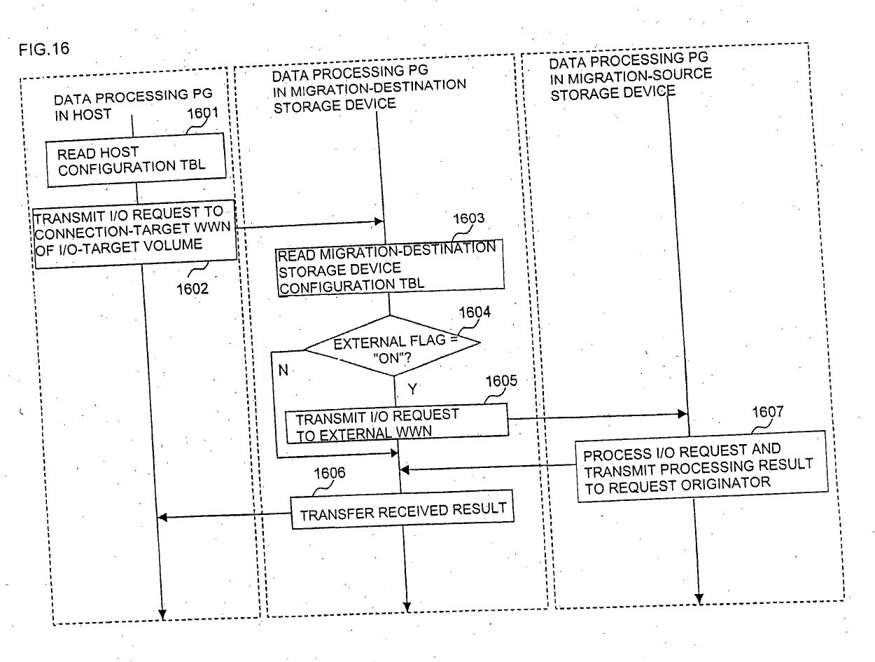

An example of an I/O processing in the external connection arrangement according to the embodiment 1 will be described. FIG. 16 illustrates a flow of a host I/O processing in the external connection arrangement. Here, the description will be made on the assumption that the host configuration TBL of the host 100 is as shown in FIG. 9, and the host 100 uses the volumes 171 and 172 of the migration-source storage device 160 via the volumes 151 and 152 of the migration-destination storage device 140 in the external connection arrangement.

The data processing PG 201 in the host 100 reads the host configuration TBL 203 in (step 1601) and transmits an I/O request to a connection-target WWN 904 of the record in the read host configuration TBL whose volume ID 901 is the same as the I/O request target volume (step 1602). Upon receiving the I/O request, the data processing PG 601 in the migration-destination storage device reads the migration-destination storage device configuration TBL 308 in (step 1603), determines whether the external flag 1204 of the record therein whose volume ID 1201 is the same as the I/O request target volume is “ON” (step 1604), and, if the external flag 1204 is “ON”, transmits an I/O request to the external WWN 1205 of the record (step 1605). Upon receiving the request, the data processing PG 701 in the migration-source storage device processes the I/O request, and transmits the result of the processing to the request source (step 1607). Upon receiving this result, the data processing PG 601 in the migration-destination storage device transfers the received result to the data processing PG 201 in the host (step 1606). Here, if the external flag 1204 is not “ON” in step 1604, the process proceeds to step 1606. According to this flow, the host can I/O access the volume without concern for whether the storage devices are in the external connection arrangement or not.

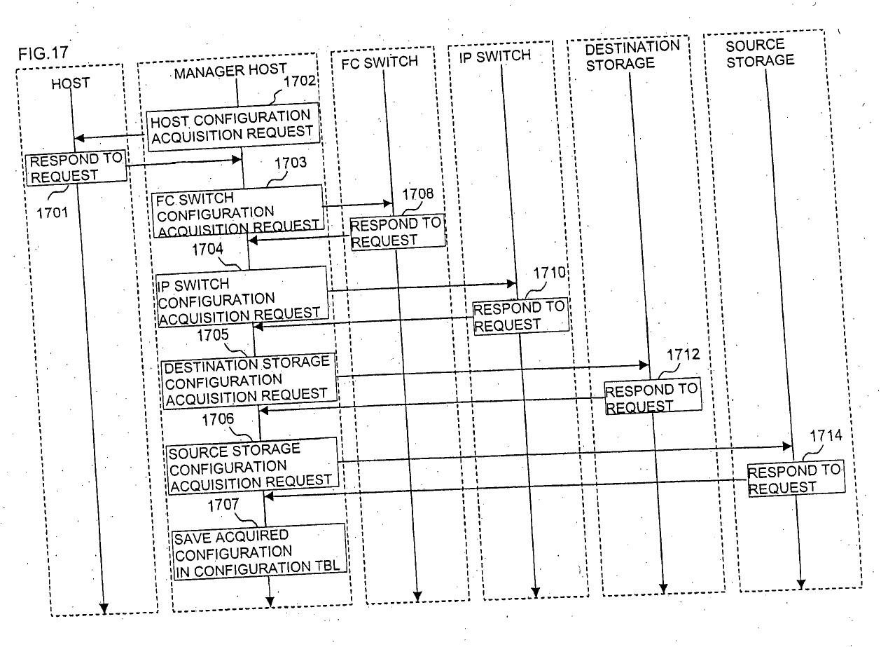

Now, a configuration acquisition processing before data copying according to the embodiment 1 will be described. FIG. 17 illustrates a flow of the configuration acquisition processing before data copying. Here, the configuration TBLs for the host 100, the FC switch 120 and the like are saved before starting data copying.

The configuration managing PG 302 in the manager host 110 transmits a host configuration acquisition request to the host 100 (step 1702). Upon receiving the request, the configuration managing-PG 202 in the host responds to the request by transmitting the host configuration to the manager host 110 (step 1701). The configuration managing PG 302 in the manager host 110 saves the host configuration in the host configuration TBL 203 (step 1707).

Then, the configuration managing PG 302 in the manager host 110 transmits an FC configuration acquisition request to the FC switch 120 (step 1703). Upon receiving the request, the configuration managing PG 402 in the FC switch responds to the request by transmitting the FC switch configuration to the manager host 110 (step 1708). The configuration managing PG 302 in the manager host 110 saves the FC switch configuration in the FC switch configuration TBL 306 (step 1707).

Then, the configuration managing PG 302 in the manager host 110 transmits an IP switch configuration acquisition request to the IP switch 130 (step 1704). Upon receiving the request, the configuration managing PG 502 in the IP switch responds to the request by transmitting the IP switch configuration to the manager host 110 (step 1710). The configuration managing PG 302 in the manager host 110 saves the IP switch configuration in the IP switch configuration TBL 307 (step 1707).

Then, the configuration managing PG 302 in the manager host 110 transmits a migration-destination storage device configuration acquisition request to the migration-destination storage device 140 (step 1705). Upon receiving the request, the configuration managing PG 602 in the migration-destination storage device responds to the request by transmitting the migration-destination storage device configuration to the manager host 110 (step 1712). The configuration managing PG 302 in the manager host 110 saves the migration-destination storage device configuration in the migration-destination storage device configuration TBL 308 (step 1707).

Then, the configuration managing PG 302 in the manager host 110 transmits a migration-source storage device configuration acquisition request to the migration-source storage device 160 (step 1706). Upon receiving the request, the configuration managing PG 702 in the migration-source storage device responds to the request by transmitting the migration-source storage device configuration to the manager host 110 (step 1714). The configuration managing PG 302 in the manager host 110 saves the migration-source storage device configuration in the migration-source storage device configuration TBL 309 (step 1707). In this way, the configuration acquisition processing before data copying is accomplished.

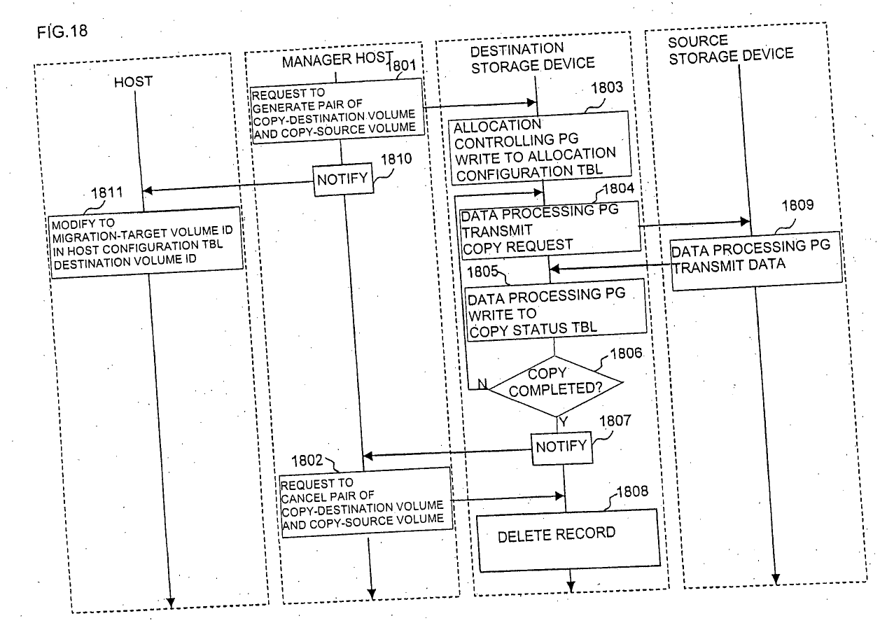

An exemplary data copy procedure according the embodiment 1 will be described. FIG. 18 illustrates a data copy procedure that is a characteristic of the present invention. Here, there will be described a case where the data in the volume 151 used in the external connection arrangement is copied into the volume 150 of the migration-destination storage device 140.

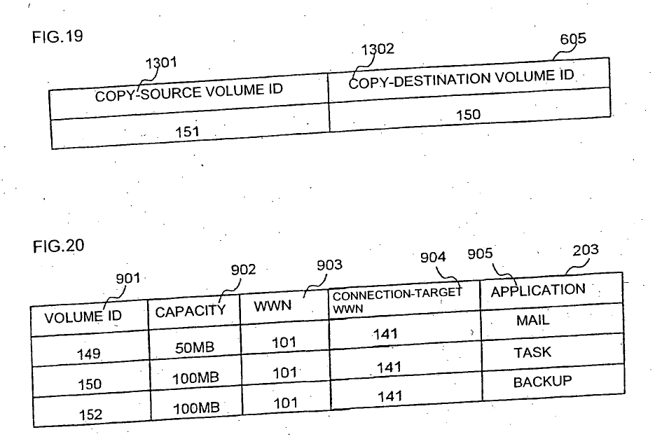

The allocation controlling command PG 301 in the manager host transmits a request to generate a pair of the copy-destination volume 150 and the copy-source volume 151 to the migration-destination storage device (step 1801). Upon receiving the request, the allocation controlling PG 604 in the migration-destination storage device writes, to the allocation configuration TBL 605, a record that designates “151” as the copy-source volume and “150” as the copy-destination volume (step 1803). After this step, the allocation configuration TBL 605 is as shown in FIG. 19.

In addition, the configuration managing PG 302 in the manager host notifies the host 100 of the transmission of the pair generation request (step 1810). Alternatively, the host 100 may inquire of the manager host 110 whether a pair is generated or not. Upon receiving the notification, the configuration managing PG 202 in the host changes the value of the volume ID 901 in the host configuration TBL 203 from 151 to 150. After this step, the host configuration TBL 203 is as shown in FIG. 20.

Once a pair is generated, the data processing PG 601 in the migration-destination storage device transmits a data copy request to copy data from the source volume to the destination volume to the migration-source storage device (step 1804). Upon receiving the request, the data processing PG 701 in the migration-source storage device transmits copy-target data to the migration-destination storage device (step 1809).

Then, the data processing PG 601 in the migration-destination storage device modifies the copy status managing TBL by changing the copy-completion flag 1403 associated with the LBA 1402 of the received data to “completed” and determines whether all the copy-completion flags 1403 in the copy status TBL 607 whose associated volume IDs 1401 identify the copy-destination volume are “completed” or not (step 1806). If all the copy-completion flags 1403 are not “completed”, step 1804 is conducted again. If all the copy-completion flags 1403 are “completed”, the data managing PG in the migration-destination storage device notifies the manager host of the completion of data migration (step 1807). Alternatively, the manager host 110 may inquire of the migration-destination storage device 140 whether the data migration is completed or not.

Once the data copying is completed, the allocation controlling command PG 301 in the manager host transmits a request to cancel the pair of the copy-destination volume 150 and the copy-source volume 151 to the migration-destination storage device (step 1802). Upon receiving the request, the allocation controlling PG 604 in the migration-destination storage device deletes the record that designates “151” as the copy-source volume and “150” as the copy-destination volume (step 1808). After this step, the allocation configuration TBL 605 is as shown in FIG. 13. In this way, the data copy procedure is accomplished.

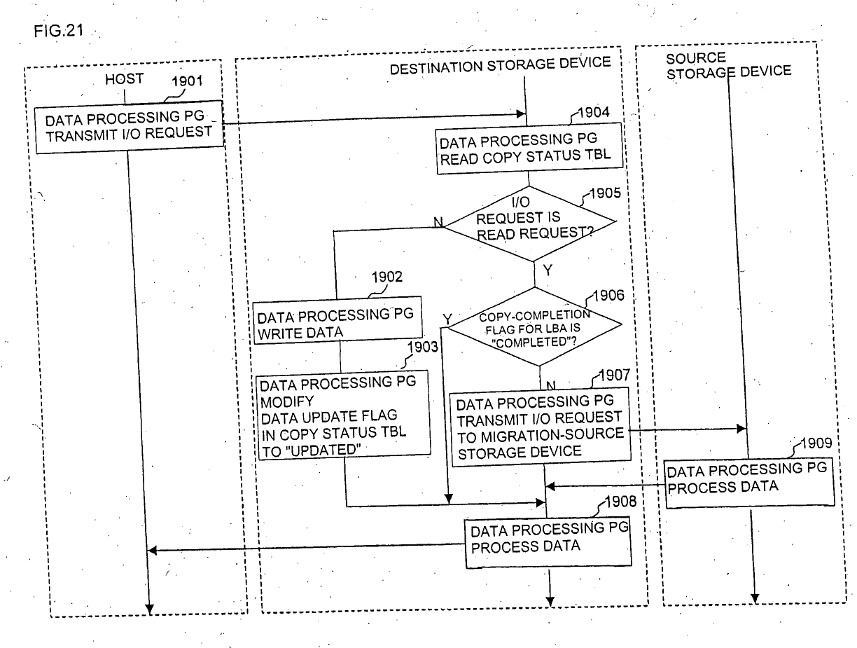

Now, an example of an I/O processing during data copying according to the embodiment 1 will be described. FIG. 21 illustrates a process flow in the case where an I/O request from the host occurs during data copying. The data processing PG 201 in the host 100 transmits an I/O request to the migration-destination storage device (step 1901).

Upon receiving the request, the data processing PG 601 in the migration-destination storage device reads the copy status TBL 607 in (step 1904) and determines whether the I/O request is a read request (step 1905). If the I/O request is a read request, the data processing PG 601 determines whether the copy-completion flag 1403 associated with the target LBA of the I/O request is “completed” or not (step 1906), and if the copy-completion flag 1403 associated with the target LBA of the I/O request is “completed”, the data processing PG 601 transmits the requested data to the host 100 (step 1908).

On the other hand, if the copy-completion flag associated with the target LBA of the I/O request is not “completed”, the data processing PG 601 transmits an I/O request to the migration-source storage device 160 (step 1907). Upon receiving the request, the data processing PG 701 in the migration-source storage device transmits the read-target data to the migration-destination storage device 140 (step 1909), and the data processing PG 601 in the migration-destination storage device 140 transmits the received data to the host (step 1908).

Furthermore, if the I/O request is not a read request (that is, it is a write request), the data processing PG 601 writes data to the write-target LBA (step 1902) and modifies the copy status TBL 607 by changing the data update flag 1404 associated with the written LBA to “updated” (step 1903). After modification, the data processing PG 601 in the migration-destination storage device 140 notifies the host of the writing (step 1908). In this way, the I/O request processing during data copying is accomplished.

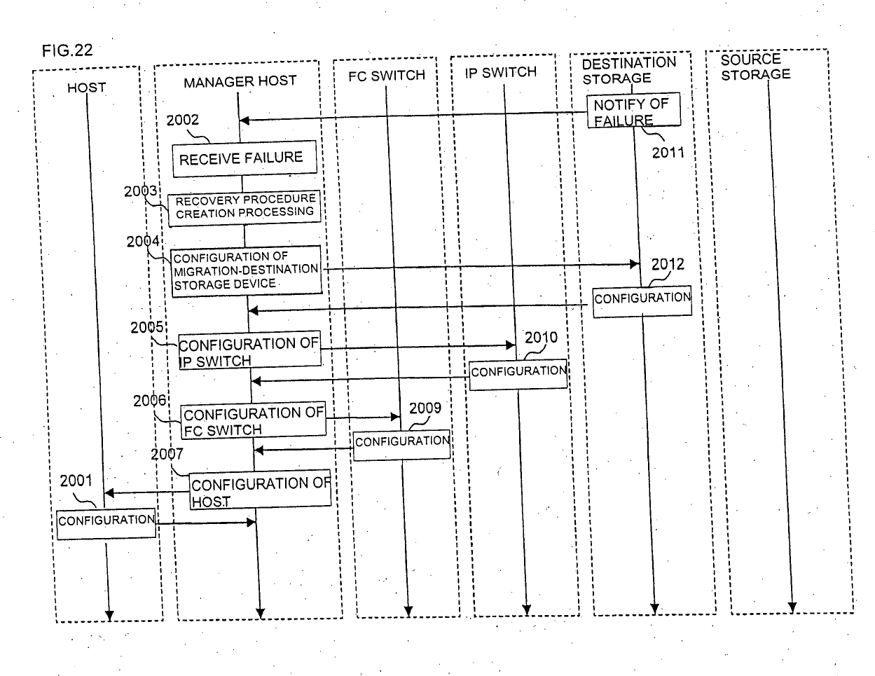

An example of a recovery processing for recovering interruption of data copying according to the embodiment 1 will be described. FIG. 22 illustrates a recovery procedure used when data copying is interrupted due to a failure or a canceling by an operator, which is a characteristic of the present invention. Once a failure, such as data copy interruption, occurs, the failure managing PG 606 in the migration-destination storage device transmits failure information to the manager host 110 (step 2011). The failure receiving PG 303 in the manager host receives the failure information (step 2002), and the configuration managing PG 302 creates a recovery procedure based on the failure information (step 2003).

Then, the configuration managing PG 302 in the manager host transmits a configuration update request to the migration-destination storage device 140 (step 2004). Upon receiving the request, the configuration managing PG 602 in the migration-destination storage device 140 updates the configuration and transmits the result back to the manager host (step 2012).

Then, the configuration managing PG 302 transmits a configuration update request to the IP switch 130 (step 2005). Upon receiving the request, the configuration managing PG 502 in the IP switch 130 updates the configuration and transmits the result back to the manager host (step 2010).

Then, the configuration managing PG 302 transmits a configuration update request to the FC switch 120 (step 2006). Upon receiving the request, the configuration managing PG 402 in the FC switch 120 updates the configuration and transmits the result back to the manager host (step 2009).

Then, the configuration managing PG 302 transmits a configuration update request to the host 100 (step 2007). Upon receiving the request, the configuration update PG 202 in the host 100 updates the configuration and transmits the result back to the manager host (step 2001). In this way, the status at the start of migration can be recovered.

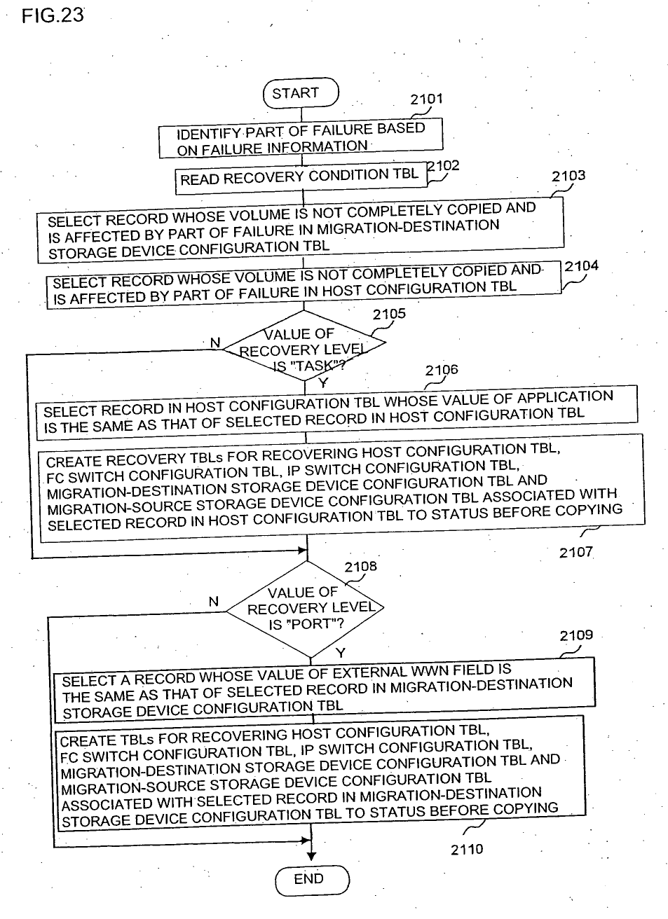

An example of a recovery TBL creation processing according to the embodiment 1 will be described. FIG. 23 illustrates a flow of a recovery TBL creation processing, which is a characteristic of the present invention. The configuration managing PG 302 in the manager host 110 identifies the part of failure based on the failure information received by the failure receiving PG 303 (step 2101) and reads the recovery condition TBL 304 from the manager host 110 (step 2102).

Then, a record whose volume is not completely copied and is affected by the part of failure is selected in the migration-destination storage device configuration TBL 308 (step 2103), and a record whose volume is not completely copied and is affected by the part of failure is selected in the host configuration TBL 203 (step 2104).

Then, the value of the recovery level 801 in the recovery condition TBL 304 is referred to to determine whether the value is “task” or not (step 2105). If the value is “task”, a record whose value of the application 905 is the same as that of the selected record in the host configuration TBL 203 is selected (step 2106), and there are created TBLs for recovering the host configuration TBL, the FC switch configuration TBL 306, the IP switch configuration TBL 307, the migration-destination storage device configuration TBL 308 and the migration-source storage device configuration TBL 309 associated with the selected record in the host configuration TBL 203 to a status before copying (step 2107).

On the other hand, if the value of the recovery level 801 in the recovery condition TBL 304 is not “task”, the value of the recovery level 801 in the recovery condition TBL 304 is referred to to determine whether the value is “port” or not (step 2108). If the value is “port”, a record whose value of the external WWN 1205 is the same as that of the selected record in the migration-destination storage device configuration TBL 308 is selected (step 2109), and there are created TBLs for recovering the host configuration TBL, the FC switch configuration TBL 306, the IP switch configuration TBL 307, the migration-destination storage device configuration TBL 308 and the migration-source storage device configuration TBL 309 associated with the selected record in the migration-destination storage device configuration TBL 308 to a status before copying (step 2110).

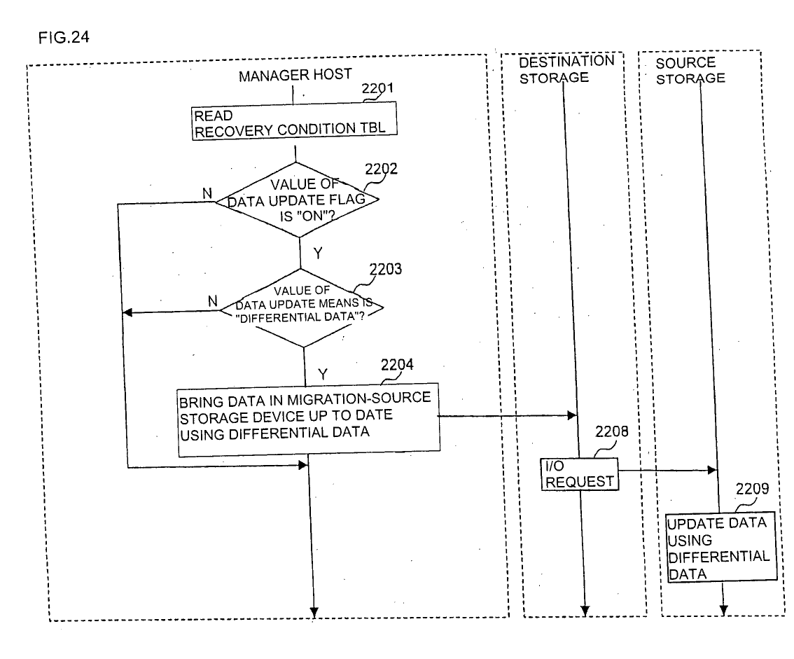

An example of a post-recovery processing according to the embodiment 1 will be described. FIG. 24 illustrates a post-recovery processing, which is a characteristic of the present invention. The configuration managing PG 302 in the manager host 110 reads the recovery condition TBL 1003 in (step 2201). Then, the configuration managing PG 302 in the manager host 110 refers to the value of the update flag 802 in the recovery condition TBL 304 to determine whether the value is “ON” or not (step 2202). If the value is “ON”, the value of the data update means 803 in the recovery condition TBL 304 is referred to to determine whether the value is “differential data” or not (step 2205). If the value is “differential data”, the manager host 110 transmits to the migration-destination storage device 140 a request to bring the volume of the migration-source storage device up to date using the differential data (step 2206). Upon receiving the request, the migration-destination storage device 140 transmits to the migration-source storage device an I/O request to apply the differential data (step 2208). Then, the migration-source storage device updates the data using the differential data (step 2209). In this way, the post-recovery processing is accomplished.

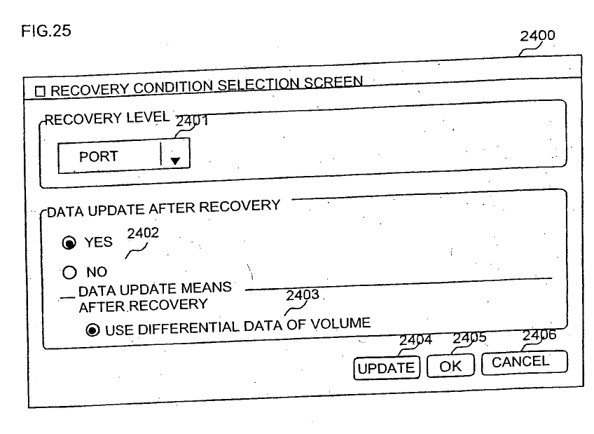

An example of a recovery condition selection screen according to the embodiment 1 will be described. FIG. 25 shows a recovery condition selection screen. A recovery condition selection screen 2400 is a screen for editing the recovery condition TBL 304. Performing manipulations in this screen to boot up the configuration managing PG 302 in the manager host 110 allows data to be registered in, edited in and deleted from the recovery condition TBL 304. The screen contains a screen update button 2404, an OK button 2405 and a cancel button 2406.

A recovery level combo box 2401 allows selection of the recovery range depending on the relationship between the range and the part of failure when a failure occurs and contains selectable recovery levels, such as “task” and “port”. However, the user may add other recovery levels to the combo box by defining the recovery levels and creating a new recovery procedure creation flow.

A post-recovery-data-update radio button 2402 is to specify whether to perform update on the data added during data migration after recovery. A post-recovery-data-update-means radio button 2403 is to specify the means for updating data.

According to this embodiment, when a volume of the migration-source storage device 160 is to be migrated into the migration-destination storage device 140, the volume before starting the data migration can be saved. Therefore, if the data migration is interrupted, the status before the start of the data migration can be recovered, and thus, the data integrity is improved. In addition, data occurring during data migration can be recovered by the post-recovery processing, and thus, the data integrity is further improved.

### Embodiment 2

An embodiment 2 of the present invention will be described schematically. In this embodiment, volumes 2366 and 2367 in a migration-destination storage device 2360 are assumed as virtual volumes 2354 and 2355 in a migration-source storage device 2350, respectively, data in the volume 2366 is migrated into the volume 2368, data in the volume 2367 is migrated into the volume 2369, a volume 2365 in the migration-destination storage device 2360 is assumed as a virtual volume 2374 in a migration-source storage device 2370, and data migration from the volume 2365 to a volume 2364 is interrupted.

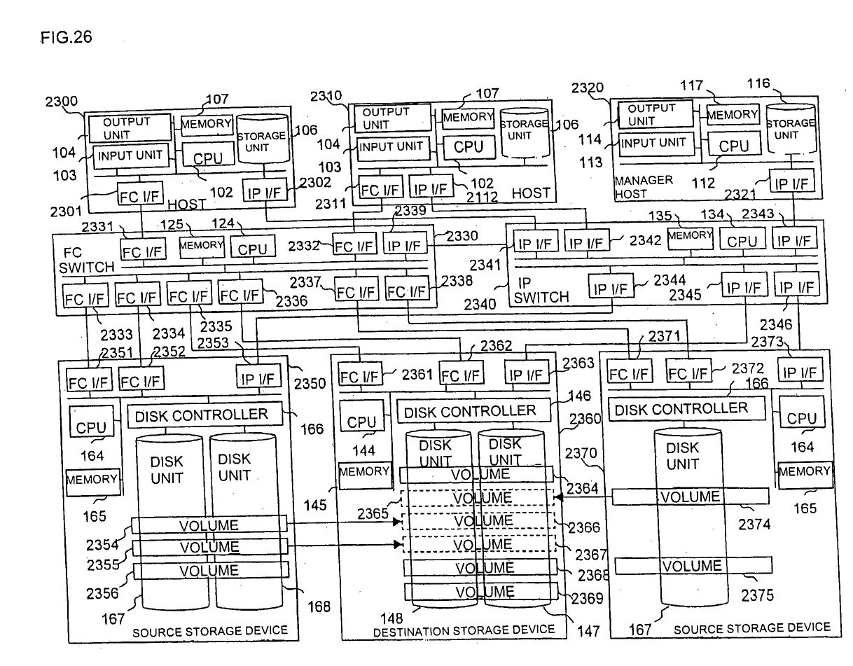

A system arrangement according to the embodiment 2 will be described. FIG. 26 shows a system arrangement according to the embodiment 2. In FIG. 26, a host 2300 is a computer that accesses the migration-destination storage device 2360 and the migration-source storage device 2350 before migration and comprises an FC I/F 2301 for transmitting/receiving input/output data to/from the migration-destination storage device 2360 and the migration-source storage device 2350, an IP I/F 2302 for transmitting/receiving management data to/from a manager host 2320, a CPU 102 for executing a program and controlling the whole of the host, a memory 107 for providing a storage area for a program, a storage unit 106 for storing a program, user data or the like, an input unit 103 that permits a user to input information, such as a keyboard and a mouse, and an output unit 104 for displaying information to a user, such as a display.

A host 2310 is a computer that accesses the migration-destination storage device 2360 and the migration-source storage device 2370 before migration and comprises an FC I/F 2311 for transmitting/receiving input/output data to/from the migration-destination storage device 2360 and the migration-source storage device 2370, an IP I/F 2312 for transmitting/receiving management data to/from a manager host 2320, a CPU 102 for executing a program and controlling the whole of the host, a memory 107 for providing a storage area for a program, a storage unit 106 for storing a program, user data or the like, an input unit 103 that permits a user to input information, such as a keyboard and a mouse, and an output unit 104 for displaying information to a user, such as a display.

The manager host 2320 is a computer that manages the hosts 2300 and 2310, the migration-source storage devices 2350 and 2370 and the migration-destination storage device 2360 and comprises an IP I/F 2321 for transmitting/receiving management data, a CPU 112 for executing a program and controlling the whole of the manager host, a memory 117 for providing a storage area for a program, a storage unit 116 for storing a program, user data or the like, an input unit 113 that permits a user to input information, such as a keyboard and a mouse, and an output unit 114 for displaying information to a user, such as a display.

An FC switch 2330 serves to transfer input/output data from the hosts 2300 and 2310 to the migration-source storage devices 2350 and 2370 and the migration-destination storage device 2360 and comprises FC I/Fs 2331, 2332, 2333, 2334, 2335, 2336, 2337 and 2338 for transmitting/receiving input/output data, an IP I/F 2339 for transferring management data, a CPU 124 for executing a program and controlling the whole of the FC switch, and a memory 125 for providing a storage area for a program.

An IP switch 2340 serves to transfer management data from the manager host 2320 to the hosts 2300 and 2310 or the like and comprises IP I/Fs 2341, 2342, 2343, 2344, 2345 and 2346 for transmitting/receiving input/output data, a CPU 134 for executing a program and controlling the whole of the IP switch, and a memory 135 for providing a storage area for a program.

The migration-destination storage device 2360 is a node for processing input/output data from the hosts 2300 and 2310 and the migration-source storage devices 2350 and 2370 and comprises FC IFs 2361 and 2362 for receiving input/output data transferred from the FC switch, an IP I/F 2363 for receiving management data from the manager host, a CPU 144 for executing a program and controlling the whole of the migration-destination storage device, a memory 145 for providing a storage area for a program, disk units 147 and 148 for storing user data, a storage controller 146 for controlling the disk units, volumes 2364, 2368 and 2369, which are sections of the disk units that are visible to the user, a volume 2365, which is a virtual internal volume of the migration-destination storage device 2360 that mimics a volume of the migration-source storage device 2370, and volumes 2366 and 2367, which are virtual internal volumes of the migration-destination storage device 2360 that mimic volumes of the migration-destination storage device 2350.

The migration-source storage device 2350 is a node for processing input/output data from the hosts 2300 and 2310 and the migration-destination storage device 2360 and comprises FC IFs 2351 and 2352 for receiving input/output data transferred from the FC switch, an IP I/F 2353 for receiving management data from the manager host, a CPU 164 for executing a program and controlling the whole of the migration-source storage device, a memory 165 for providing a storage area for a program, disk units 167 and 168 for storing user data, a disk controller 166 for controlling the disk units, and volumes 2354 and 2355, which are sections of the disk units that are visible to the user.

The migration-source storage device 2370 is a node for processing input/output data from the hosts 2300 and 2310 and the migration-destination storage device 2360 and comprises FC IFs 2371 and 2372 for receiving input/output data transferred from the FC switch, an IP I/F 2373 for receiving management data from the manager host, a CPU 164 for executing a program and controlling the whole of the migration-source storage device, a memory 165 for providing a storage area for a program, a disk unit 167 for storing user data, a disk controller 166 for controlling the storage device and a volume 2374, which is a section of the disk unit that is visible to the user.

Configuration acquisition processings before data copying, a data copy procedure and an I/O processing during data copying according to the embodiment 2 are the same as those according to the embodiment 1 and, thus, will not be described herein.

An example of a recovery processing for recovering interruption of data copying according to the embodiment 2 will be described. FIG. 22 illustrates a recovery procedure used when data copying is interrupted due to a failure or a canceling by an operator, which is a characteristic of the present invention. This procedure is similar to the procedure according to the embodiment 1. However, there will be described in detail a case where a failure occurs during data migration from the volume 2367 to the volume 2369, and the part of failure is the FC I/F 2352, which is a port that is necessary for using a volume of the migration-source storage device 2350 via a virtual volume of the migration-destination storage device 2360.

Once a failure occurs, a failure managing PG 606 in the migration-destination storage device 2360 transmits failure information to the manager host 2320 (step 2011). A failure receiving PG 303 in the manager host 2320 receives the failure information (step 2002), and a configuration managing PG 302 creates a recovery procedure based on the failure information (step 2003) and transmits a configuration update request to the migration-destination storage device 2360 (step 2004). Upon receiving the request, a configuration managing PG 602 in the migration-destination storage device 2360 updates the configuration and transmits the result back to the manager host (step 2012).

Then, the configuration managing PG 302 in the manager host 2320 transmits a configuration update request to the IP switch 2340 according to the created recovery procedure (step 2005). Upon receiving the request, a configuration managing PG 502 in the IP switch 2340 updates the configuration and transmits the result back to the manager host (step 2010).

Then, the configuration managing PG 302 transmits a configuration update request to the FC switch 2330 according to the created recovery procedure (step 2006). Upon receiving the request, a configuration managing PG 402 in the FC switch 2330 updates the configuration and transmits the result back to the manager host (step 2009).

Then, the configuration managing PG 302 transmits a configuration update request to the hosts 2300 and 2310 according to the created recovery procedure (step 2007). Upon receiving the request, the configuration update PG 202 in the hosts 2300 and 2310 updates the configuration and transmits the result back to the manager host (step 2001). In this way, the status at the start of migration can be recovered.

An example of a recovery TBL creation processing according to the embodiment 2 will be described. FIG. 23 illustrates a flow of a recovery TBL creation processing, which is a characteristic of the present invention. Although this procedure is similar to the procedure according to the embodiment 1, it will be described in detail.

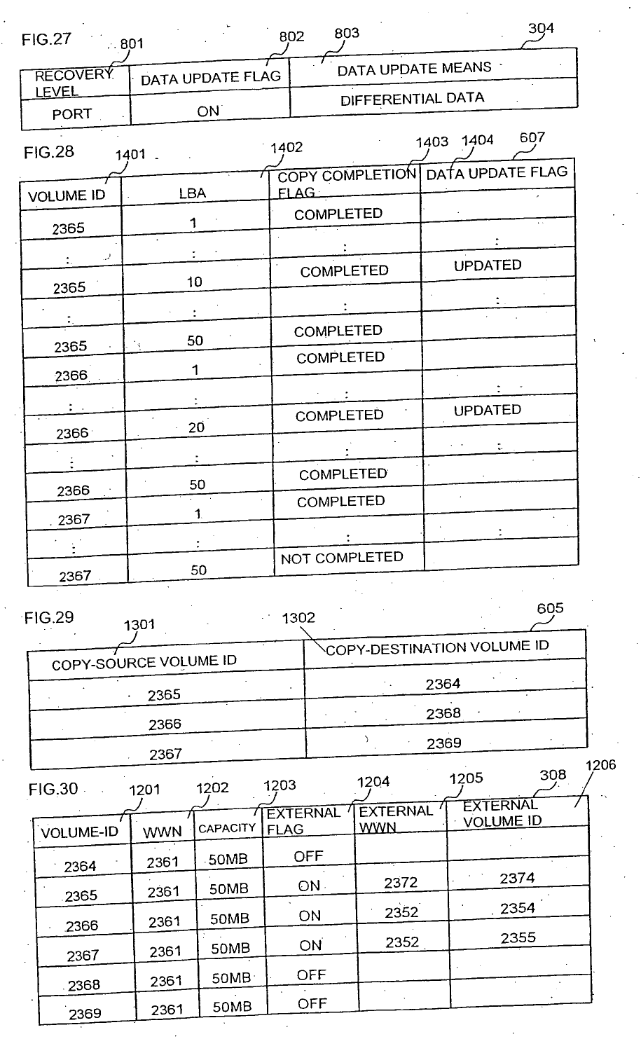

The configuration managing PG 302 in the manager host 2320 identifies the part of failure based on the failure information received by the failure receiving PG 303 (step 2101) and reads a recovery condition TBL 304 shown in FIG. 27 (step 2102).

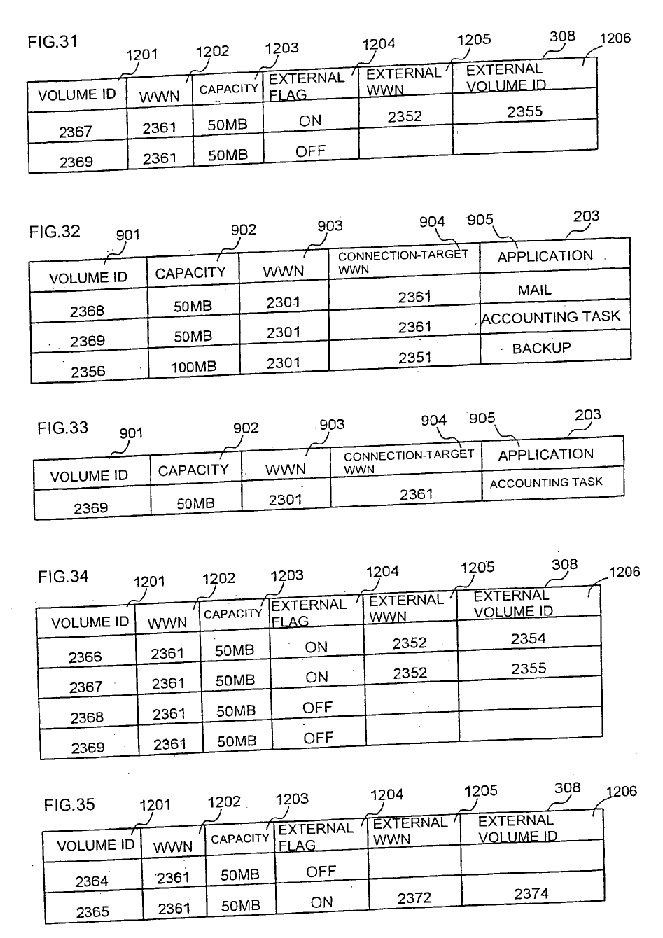

Then, a record whose volume is not completely copied and is affected by the part of failure is selected in a migration-destination storage device configuration TBL 308 (step 2103). Referring to a copy status managing TBL shown in FIG. 28, it can be seen that the failure occurs when the volume 2367 is being copied. Referring to a pair arrangement configuration TBL 605 shown in FIG. 29, the copy destination of the volume 2367 that is not completely copied is the volume 2369, and thus, copying is not completed for the volume 2369. In the migration-destination storage device configuration TBL 308 during data migration shown in FIG. 30, records whose volumes are volumes 2367 and 2369, which are not completely copied, and whose external WWN is the FC I/F 2352, which is the part of failure, are selected. That is, the records shown in FIG. 31 are selected.

Then, a record whose volume is not completely copied and is affected by the part of failure is selected in a host configuration TBL 203 in the host 2300 (step 2104). In this embodiment, in the host configuration TBL 203 during data migration shown in FIG. 32, a record whose volume ID is the same as that of the record that is affected by the part of failure in the migration-destination storage device configuration TBL 308 shown in FIG. 31 is selected. Then, the host configuration TBL 203 shown in FIG. 33 results. The volume of the record that is affected by the part of failure in the migration-destination storage device configuration TBL 308 shown in FIG. 31 is not used, and thus, no record is selected.

Then, the value of the recovery level 801 in the recovery condition TBL 304 is referred to to determine whether the value is “task” or not (step 2105). In this embodiment, the value is not “task”, and the process proceeds to the next step.

Then, the value of the recovery level 801 in the recovery condition TBL 304 is referred to to determine whether the value is “port” or not (step 2108). In this embodiment, the value is “port”, and thus, a record whose external WWN field is the same as that of the selected record in the migration-destination storage device configuration TBL shown in FIG. 31 is selected.

Then, there are created TBLs for recovering the FC switch configuration TBL, the IP switch configuration TBL, the migration-destination storage device configuration TBL and the migration-source storage device configuration TBL associated with the selected record in the migration-destination storage device configuration TBL shown in FIG. 31 to a status before data migration (step 2110).

The migration-destination storage device configuration TBL 308 for recovery contains records resulting from deletion of the record including the volume 2366 whose external WWN is the same as the selected record in the migration-destination storage device configuration TBL shown in FIG. 34 and the record including the volume 2368, which is the copy-destination volume of the volume 2366, from the selected migration-destination storage device configuration TBL shown in FIG. 34.

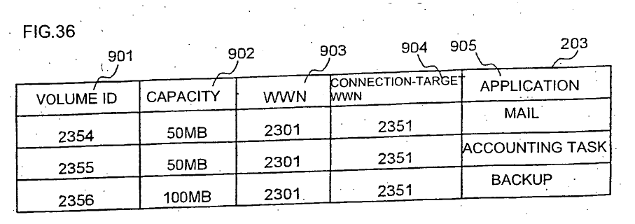

The host configuration TBL 203 of the host 2300 for recovery contains records resulting from deletion of the records whose volumes are the same as those in the migration-destination storage device configuration TBL 308 shown in FIG. 34 from the host configuration TBL of the host 2300 shown in FIG. 32 and modification for making the host to use volumes of the migration-source storage device, as shown in FIG. 36.

The host configuration TBL 203 in the host 2310 does not use any volume affected by the failure and therefore need not be recovered.

The FC switch configuration TBL 306 in the FC switch 2330 is not modified due to the failure and therefore need not be recovered.

The IP switch configuration TBL 307 in the IP switch 2340 is not modified due to the failure and therefore need not be recovered.

The migration-source storage device configuration TBL 309 in the migration-source storage device 2350 is not modified due to the failure and therefore need not be recovered.

The migration-source storage device configuration TBL 309 in the migration-source storage device 2370 is not modified due to the failure and therefore need not be recovered.

The post-recovery processing according to the embodiment 2 is the same as that according to the embodiment 1 and thus will not be described.

Embodiments of the present invention have been described above. An implementation 1 of the present invention is the computer system, in which said one storage device saves data written by said computer during data copying from said second storage area into said first storage area only in said first storage area.

An implementation 2 of the present invention is the computer system, in which said one storage device has a disk unit and a memory storing a data processing program, a configuration managing program, a migration-destination storage device configuration program, an allocation controlling program, an allocation configuration program, a failure managing program and a copy status managing table, assumes a virtual volume in itself as a copy-source volume in the storage device having said second storage area to said computer, and copies data from the virtual volume to a copy-destination volume.

An implementation 3 of the present invention is a storage device connected to a computer via a network along with other storage devices, in which the storage device has a first storage area, allows said computer to access a second storage area in one or more of said other storage devices via itself, allocates the first storage area for copy of data from said second storage area and copies the data from said second storage area into said first storage area.

An implementation 4 of the present invention is the storage device, in which data written by said computer during data copying from said second storage area into said first storage area is saved only in said first storage area.

An implementation 5 of the present invention is the storage device, in which the data written by said computer to said first storage area during data copying from said second storage area of said second storage device into said first storage area is capable of being separately extracted from said first storage area.

An implementation 6 of the present invention is the storage device, in which, when data copying from the second storage area of said second storage device into said first storage area is interrupted, the extracted data written by said computer during copying is capable of being written to the second storage area.

An implementation 7 of the present invention is computer software stored in a storage device, in which the computer software comprises a program that is executed by said storage device to allow a computer to use data in a second storage area that is not completely copied when data copying from the second storage area into a first storage area is interrupted.

An implementation 8 of the present invention is the computer software, in which said first storage area and said second storage area are each comprised of a plurality of storage sub-areas, a plurality of copy processings are performed from said second storage area into said first storage area, and the computer software comprises a program that is executed by said storage device to allow said computer to use data in the plurality of storage sub-areas in said second storage area when one or more of the plurality of copy processings are interrupted.

An implementation 9 of the present invention is the computer software, in which the computer software is comprised of a program that is executed by said storage device to allow said computer to use data in a sub-area of the first storage area if the data copying into the sub-area is completed or to use data in a sub-area of the second storage area if the data copying into the sub-area of the first storage device corresponding to the sub-area of the second storage area is not completed, when one or more of said plurality of copy processings are interrupted,

An implementation 10 of the present invention is a data migration method in a computer system having a computer, a first storage device connected to the computer and a second storage device connected to the first storage device, the computer, the first storage device and the second storage device being interconnected via a network, in which said first storage device has a first storage area, allows said computer to access a second storage area in said second storage device via itself, allocates the first storage area for copy of data from said second storage area and copies data from said second storage area into said first storage area.

What is claimed is:

1. A computer system, comprising:
a computer; and
a plurality of storage devices connected to the computer via a network,
wherein one of the storage devices has a first storage area, allows said computer to access a second storage area in one or more other storage devices via itself, allocates the first storage area for copy of data from said second storage area and copies data from said second storage area into said first storage area.

2. The computer system according to claim 1, wherein said one storage device saves data written by said computer during data copying from said second storage area into said first storage area only in said first storage area.

3. The computer system according to claim 1, wherein said one storage device has a disk unit and a memory storing a data processing program, a configuration managing program, a migration-destination storage device configuration program, an allocation controlling program, an allocation configuration program, a failure managing program and a copy status managing table, assumes a virtual volume in itself as a copy-source volume in the storage device having said second storage area to said computer, and copies data from the virtual volume to a copy-destination volume.

4. A storage device connected to a computer via a network along with other storage devices,
wherein the storage device has a first storage area, allows said computer to access a second storage area in one or more of said other storage devices via itself, allocates the first storage area for copy of data from said second storage area and copies the data from said second storage area into said first storage area.

5. The storage device according to claim 4, wherein data written by said computer during data copying from said second storage area into said first storage area is saved only in said first storage area.

6. The storage device according to claim 4, wherein the data written by said computer to said first storage area during data copying from said second storage area of said second storage device into said first storage area is capable of being separately extracted from said first storage area.

7. The storage device according to claim 4, wherein, when data copying from the second storage area of said second storage device into said first storage area is interrupted, the extracted data written by said computer during copying is capable of being written to the second storage area.

8. Computer software stored in a storage device according to claim 4, wherein the computer software comprises a program that is executed by said storage device to allow a computer to use data in a second storage area that is not completely copied when data copying from the second storage area into a first storage area is interrupted.

9. The computer software according to claim 8, wherein said first storage area and said second storage area are each comprised of a plurality of storage sub-areas, a plurality of copy processings are performed from said second storage area into said first storage area, and the computer software comprises a program that is executed by said storage device to allow said computer to use data in the plurality of storage sub-areas in said second storage area when one or more of the plurality of copy processings are interrupted.

10. The computer software according to claim 8, wherein the computer software is comprised of a program that is executed by said storage device to allow said computer to use data in a sub-area of the first storage area if the data copying into the sub-area is completed or to use data in a sub-area of the second storage area if the data copying into the sub-area of the first storage device corresponding to the sub-area of the second storage area is not completed, when one or more of said plurality of copy processings are interrupted,

11. A data migration method in a computer system having a computer, a first storage device connected to the computer and a second storage device connected to the first storage device, the computer, the first storage device and the second storage device being interconnected via a network,
wherein said first storage device has a first storage area, allows said computer to access a second storage area in said second storage device via itself, allocates the first storage area for copy of data from said second storage area and copies data from said second storage area into said first storage area.
